(19) United States
(12) Patent Application Publication
(10) Pub. No.: US 2026/0293127 A1
(43) Pub. Date: Sep. 24, 2026

(54) 3D-DRAM WITH EXPANDED SECTION LAYOUT

(71) Applicant: Micron Technology, Inc., Boise, ID (US)

(72) Inventor: Hiroki Fujisawa, Kanagawa (JP)

(73) Assignee: Micron Technology, Inc., Boise, ID (US)

(21) Appl. No.: 19/556,081

(22) Filed: Mar. 4, 2026

Related U.S. Application Data
(60) Provisional application No. 63/776,496, filed on Mar. 24, 2025.

(51) Int. Cl. H10B 12/00; G11C 11/408; G11C 11/4091

(52) U.S. Cl. CPC H10B 12/50; G11C 11/4085; G11C 11/4091; H10B 12/30

(57) ABSTRACT

A 3D memory device includes multiple memory patches each of which includes a 3D array of memory cells arranged at the intersection of word lines running in a first direction, local digit lines (LDLs) running in a second direction, and global digit lines (GDLs) running in a third direction. The GDLs are coupled to sense amplifiers. For example, a first set of sense amplifiers are coupled to even ones of a first half of the GDLs, a second set are coupled to even ones of a second half of the GDLs, a third set are coupled to odd ones of the first half of the GDLs, and a fourth set are coupled to odd ones of the second half of GDLs. The first and the fourth set of sense amplifiers may be positioned above the array, while the second and third sets are not.

### CROSS REFERENCE TO RELATED APPLICATION(S)

This application claims the benefit under 35 U.S.C. § 119 of the earlier filing date of U.S. Provisional Application Serial No. 63/776,496 filed March 24, 2025. The aforementioned application is incorporated herein by reference, in its entirety, for any purpose.

### BACKGROUND OF THE INVENTION

Memory devices, such as DRAM devices have generally decreased in size and increased in capacity over time. Many of these gains have been accomplished by miniaturizing circuits such as the sense amplifier, sub-word line driver, and so for forth across different generations of memory devices. However, it is difficult to decrease the size of components below certain size thresholds, which makes it difficult to continue to improve memory device capacity and size in this manner.

It may be possible to increase memory device size and capacity by arranging memory cells in a three dimensional grid instead of a two-dimensional array. For example, multiple memory chips may be stacked on top of each other. However, this increases the thickness of the overall memory device to an extent that may be difficult to accommodate and the number of stacked chips is limited by concerns such as the length of signal lines through the stack, alignment of timing signals, and so forth. Other technologies may be used to generate 3D arrays of memory cells, such as the 3D arrays found in flash memory, but these may have limitations in the speed at which the memory device operates and are generally much slower than the speeds required of a DRAM device. There may be a need for 3D memory devices which operate at high speeds.

### BRIEF DESCRIPTION OF DRAWINGS

FIG. 1 is a block diagram of a 3D memory device according to some embodiments of the present disclosure.

FIG. 2A is a perspective drawing of a single die memory die with an inset showing a ‘top down’ view of two example memory sections according to some example embodiments of the present disclosure.

FIG. 2B is a perspective drawing of a memory device where circuit elements are placed over the memory patches, with a inset showing a ‘top down’ view of two example memory sections according to some example embodiments of the present disclosure.

FIG. 3 is a perspective schematic diagram of a portion of a 3D memory array according to some embodiments of the present disclosure.

FIG. 4 is a perspective view of a portion of a memory device according to some embodiments of the present disclosure.

FIG. 5 is a cross sectional view of a memory device according to some embodiments of the present disclosure.

FIG. 6 is a cross sectional view of a memory device according to some embodiments of the present disclosure.

FIG. 7 is a cross sectional view of a memory device according to some embodiments of the present disclosure.

FIG. 8 is a flow chart of a method of selectively coupling local digit lines to global digit lines in a 3D memory device according to some embodiments of the present disclosure.

### DETAILED DESCRIPTION OF THE INVENTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells which store information. For example each memory cell may store a single bit of information as a charge on a capacitive element. In a conventional 2D memory device, the memory cells are logically organized at the intersection of rows and columns. Conductive elements known as word lines couple memory cells along a row, and conductive elements known as digit lines or bit lines couple memory cells along a column. Accordingly, a row address may be used to specify a word line and a column address may be used to specify one or more of the digit lines.

The memory array may be formed of repeating units, referred to as ‘sections’ or ‘tiles’. These sections include one or more patches of the memory array and various circuits which support the operation of that patch. For example, a section may include the patch, sense amplifiers (SA) coupled to the digit lines of that patch, and sub-word line drivers (SWD) coupled to the word lines of the patch. For example, in a conventional 2D memory device, the memory array patch may be generally rectangular with SAs positioned along a ‘top’ and ‘bottom’ edge of the patch and SWDs positioned along a ‘left’ and ‘right’ edge. The top row of sense amplifiers are coupled to either even or odd digit lines (in this and in an adjacent patch), the bottom row of sense amplifiers are coupled to the other digit lines (in this and in an adjacent patch). The SWDs along the edges are similarly coupled to alternate word lines in the patch.

While this layout may be efficient for 2D memory devices, when a third dimension is added, it may become more complicated to generate sections which are compact and which repeat across the memory device. For example, the need for connections to run in a third axis may complicate the placement of components such as SAs and SWDs compared to 2D memory. In addition, the expansion into a third dimension may increase the memory cell density enough that it is possible to relax the pitch or spacing between components, which may allow more flexible layouts to be used compared to the layouts which are possible with the stringent pitch requirements of 2D memory. For example, a 3D memory device may have generally greater spacing between components such as word lines, sense amplifiers, and sub-word line drivers compared to a 2D memory. There may be a need for new section layouts in 3D-DRAM devices.

The present disclosure is drawn to apparatuses, systems, and methods for 3D-DRAM with expanded section layouts. An example 3D-DRAM device includes memory cells arranged at the intersection of word lines and local digit lines with the local digit lines coupled together by global digit lines. The word lines, local digit lines, and global digit lines may generally extend in directions which are mutually orthogonal to each other. The present application uses the convention that the word lines generally extend along an ‘x’ direction, the local digit lines generally extend along a ‘z’ direction, and the global digit lines generally extend along a ‘y’ direction. The x, y, and z directions may be orthogonal to each other.

Each section includes one or more memory patches which include a 3D array of memory cells. A key limitation for the overall size of the patch may be the number of local digit lines which are coupled to each global digit line. For example, each local digit line may increase the capacitance of the overall global digit line. In some example embodiments, the present disclosure relates to 3D memory devices where the local digit lines are selectively coupled to the associated global digit line by a multiplexer which acts a switch. For example, each global digit line has an associated set of local digit lines. Responsive to a row address, a subset of that set of local digit lines is coupled through respective multiplexers to the global digit lines, while the remainder of the set of local digit lines are isolated from the global digit line. Since only a subset of the associated local digit lines are coupled to each global digit line, the overall capacitance of the global digit line and coupled local digit lines is kept manageable. This, in turn, may allow more local digit lines and thus more memory cells to be associated with each global digit line, allowing an increase in the number of memory cells in each patch.

An example implementation may include a number of multiplexer drivers, each coupled between a subset of local digit lines and their associated global digit line. For example, there may be a multiplexer driver for each pair of local digit lines. The memory device includes a number of multiplexer drivers, each of which selectively activates a number of the multiplexers in common. The multiplexers may be coupled together by multiplexer driver signal lines extending in the x direction. A global row driver activates one of the multiplexer drivers based on a row address, and the multiplexer driver selectively couples the selected subset of local digit lines to each of the global digit lines. In this way, which multiplexer driver may be used to selectively couple the subset of local digit lines which intersect the active word line to the global digit lines. In other words, when a row address is received, a word line associated with that row address is activated and the local digit lines which intersect that word line are selectively coupled to respective global digit lines, and through those to the sense amplifiers.

In some embodiments, the present disclosure may include selectively coupling a local digit line to the respective global digit line for both a signal global digit line and a reference global digit line. For example, each sense amplifier may be coupled to two global digit lines. In an example operation, a word line is activated which is coupled to the sense amplifier along one of the two global digit lines which acts a signal digit line while the other global digit line acts as a reference. To match the capacitance of the two global digit lines, multiplexers may selectively couple equivalent local digit lines to both the signal and reference global digit lines. In some embodiments, the present disclosure may include bleed transistors which couple the local digit lines which were not selected by the multiplexer driver signal to a ground voltage so they do not ‘float’.

In some aspects, the present disclosure relates to positioning certain elements related to the section over the array patches. The memory device may be implemented across two dies, a first die which includes the memory array patches, and a second die positioned over that die in the z direction which includes circuits such as the sense amplifiers, sub-word line drivers and multiplexer drivers. When the memory patch areas are large enough, for example because multiplexer drivers are used, the areas which include certain circuits in the second die may be positioned such that they are directly above the memory patches in the second die. For example, when viewed in a ‘top-down’ fashion, in the xy plane, certain circuit regions may overlap the memory patches.

An example implementation may position a portion of the sense amplifiers associated with a memory patch directly over that memory patch. The sense amplifiers for a given patch may be divided into first sense amplifier region and a second sense amplifier region. For example, the first sense amplifier region may include sense amplifiers which are coupled to ‘even’ global digit lines while the second sense amplifier region includes sense amplifiers which are coupled to ‘odd’ global digit lines or vice versa. Each sense amplifier region includes two portions. For example, the first region includes a first portion and a second portion and the second region includes a third portion and fourth portion. In each region, one of the two portions is positioned over the associated patch while the other portion is positioned over an adjacent memory patch.

In some embodiments of the present disclosure, a memory device may use both multiplexers to selectively couple local digit lines to global digit lines and use sense amplifier regions positioned over the array patch together. In some embodiments, multiplexers may be used along, for example in devices where the sense amplifiers are not positioned above the patch region. In some embodiments, sense amplifiers may be positioned above a memory patch which does not use multiplexers to selectively couple local and global digit lines.

In some aspects, the present application relates to the spatial arrangement of various components. As used herein, when a circuit element is referred to as extending in or along a direction or axis, it refers to a component that is primarily extended in that dimension. However, such an element need not be a perfect line and may have portions which do not exclusively run in the given direction. For example, while a word line may primarily extend along the x axis, it may have portions which extend in the y and/or z directions. As used herein, when a component is referred to as being ‘above’ or ‘below’ another component, it means that at least a portion of the footprint of that component overlaps at least a portion of the footprint of the other component when projected on at least one plane but that they are offset in at least one axis. For example, in some embodiments the sense amplifier region may be above the array patch in the z direction. At least a portion of the xy footprint of the sense amplifier region overlaps at least a portion of the xy footprint of the array patch region, however the sense amplifier region occupies a different range of space long the z coordinate than the array patch region.

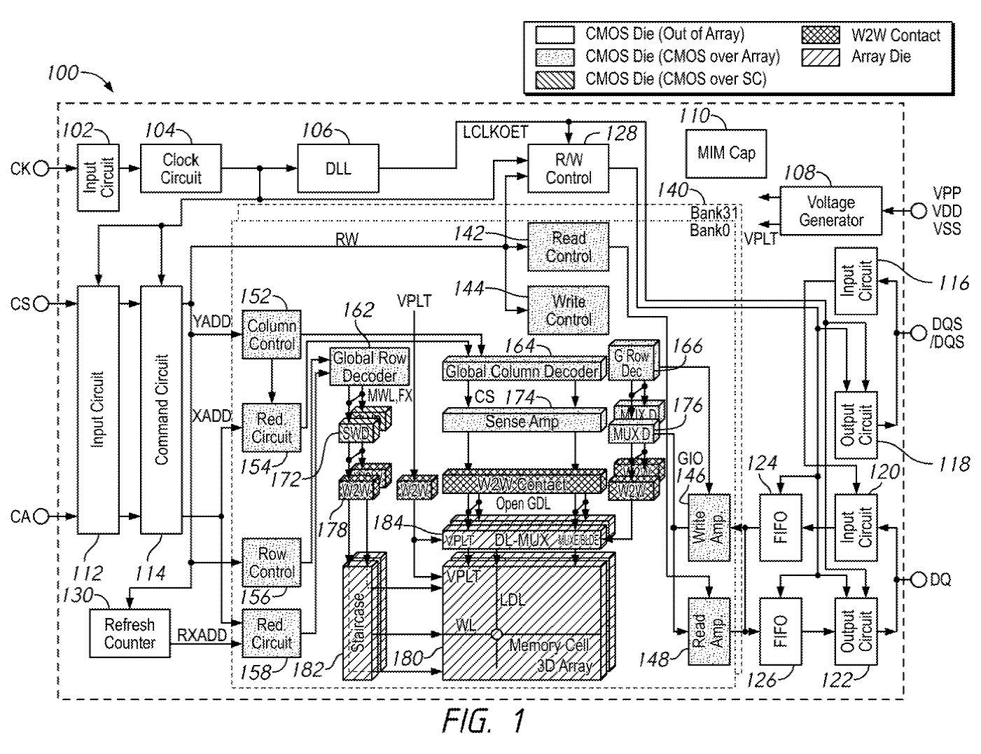

FIG. 1 is a block diagram of a 3D memory device according to some embodiments of the present disclosure. The view of the 3D memory device 100 in FIG. 1 is a block diagram representing the different components of the 3D memory device 100. It does not represent the spatial layout of the components of the device, except where otherwise noted.

The 3D memory device 100 may be coupled to a controller (not shown in FIG. 1) which provides various commands, data, and other signals to the memory device 100 to operate the memory. In some embodiments, the 3D memory device 100 may be a stand-alone device. In some embodiments the 3D memory device 100 may be part of a module that packages together several similar memory devices.

The 3D memory device 100 includes a number of external terminals which receive various signals which are used by the device 100. The signals which are received, as well as the signals within the memory device 100, are generally represented by voltages, which different levels of voltage representing different states of the signal. For example, many of the signals used by the memory device 100 may be binary signals, where a first voltage level represents a logical high and a second voltage level represents a logical low. Example terminals include a clock terminal CK, a chip select terminal CS, a command/address terminal CA, data strobe terminals DQS and /DQS, data terminals DQ, and voltage terminals such as VPP, VDD, and VSS. Any of those example terminals may include one or more individual terminals.

The clock signal CK is received by the clock terminal and provided through an input circuit 102 to a clock circuit 104. The clock signal CK is used to control the timing of operations in the memory device 100. The clock circuit 104 generates one or more internal clock signals based on the external clock signal CK and distributes them to various other components of the memory device 100. The clock circuit 104 also provides the clock signal to a delay locked loop (DLL) circuit 106 which generates a delayed clock signal LCLKOET. The delayed clock circuit may be used to match a timing it takes the clock signal to propagate through the memory device 100 and may be used to time read operations. The 3D memory device 100 also receives and provides data strobes DQS and /DQS through a respective input circuit 116 and output circuit 118. During write operations the memory receives a data strobe signal used to time operations of the input circuit 120 for the data DQ. During read operations the memory 100 provides the delayed clock signal LCLKOET to time the operations of a data output circuit 122 to the data terminal DQ. Buffer circuits 124 and 126 are used to serialize or deserialize data between the memory device and the DQ terminals.

The memory device 100 receives voltages at voltage terminals. The voltages are provided to a voltage generator circuit 108 which generates one or more internal voltages based on the provided voltages. The provided voltages as well as the generated voltages are distributed to the various circuits of the memory device 100. For example, the memory device 100 may receive a ground voltage VSS and a system voltage VDD as well as a voltage VPP. The memory includes a MIM capacitor 110 which may be used to help regulate voltages in the device 100.

The memory receives commands and addresses along a command/address bus coupled to CA terminals. The 3D memory device 100 also receives a chip select signal CS, which is used to time signals along the CA terminals, as well as indicate which memory device 100 is receiving commands and addresses in embodiments where multiple memory devices are packaged together. The CS and CA signals are passed through an input circuit 112 to a command/address circuit 114. Examples of addresses include bank address BADD which specifies a bank of the memory device 100, row address XADD which specifies a row of the device, and column address YADD which specifies a column of the device. Examples of commands include activation commands ACT, pre-charge commands PRE, access commands such as read R or write W, or refresh commands. Certain commands and addresses may generally be received together. For example, the CA terminal may receive a row activation command ACT along with a row address XADD and bank address BADD. Access commands such as read or write may generally be received along with a column address YADD. A read/write control circuit 128 helps manage the RW commands.

The 3D memory device 100 is divided into one or more memory banks 180. In the embodiment of FIG. 1, there are 32 banks, labelled Bank0 to Bank31. More or fewer banks may be used in other example embodiments. Each bank is associated with a bank logic region 140, which includes the memory array 180 of the bank as well as various circuits associated with that bank. These circuits may generally be repeated on a bank-by-bank basis. An example bank logic region 140 may include a column control circuit 152 and column redundancy circuit 154, a row control circuit 156 and row redundancy circuit 158, global row decoders 162 and 166, global column decoder 164, sub-word line drivers 172, sense amplifiers 174, multiplexer drivers 176, the array 180 and staircase region 182, digit line multiplexers 184, write amplifiers 146 and read amplifiers 148.

The array 180 is a 3D array with memory cells coupled at the intersection of word lines WL and local digit lines LDL. The view of FIG. 1 shows an example slice of the array through an xz plane, showing an example WL and LDL. The LDLs are coupled together along a y axis by global digit lines GDL. The GDLs couple to the sense amplifiers 174. In some embodiments, multiplexers 184 are used to select which LDL(s) are coupled to the respective GDL, and through that GDL to the sense amplifier. A global row decoder 166 is used to selectively activate multiplexer drivers 176 based on the row address, which activate respective ones of the multiplexers 184. In some embodiments, the multiplexers 184 and their respective drivers 176 may not be used and may be eliminated.

The row control circuit 156 activates a word line of the memory array 180 based on the row address. The row control circuit 156 provides internal signals to global row decoder circuits 162 and 166. The global row decoder circuit 162 activates a sub-word line driver 172 associated with the word line specified by XADD. The sub-word line driver 172 is coupled to an associated word line WL through the staircase 182. The sub-word line driver selected by the row address activates the associated word line, causing the memory cells along that word line coupled to the intersecting local digit lines LDLs. The LDLs in turn are coupled along intersecting global digit lines to the sense amplifiers. In some embodiments, the global row decoder circuit 166 activates a multiplexer driver 176 which in turn selects multiplexers 184 to couple the LDLs which intersect the selected word line to the GDLs.

The global row decoder circuit 166 receives the row address XADD and uses the row address to determine which multiplexer(s) 176 to activate. Based on the row address the global row decoder circuit 166 provides decoded address to the multiplexer drivers 176, and the multiplexer driver(s) associated with the decoded address provide a multiplexer driver signal. The multiplexers 176 may be grouped together in sets, and the sets are coupled in common to a multiplexer driver 176 provides the multiplexer driver signal, the multiplexers in the set are activated and couple the associated LDL to the GDL. In some embodiments, when the multiplexer driver signal is inactive, the LDL may be decoupled from the GDL and coupled to a ground voltage instead.

The column control circuit 152 selects global digit lines to couple to global input/output lines GIO based on the column address YADD. During a write operation, the GIO lines are coupled to a write amplifier 146, which provides data received from the input circuit 120 through the GIO lines to the selected GDL lines and through those to the memory cells at the intersection of the selected WL and LDL. During a read operation, the data from the memory cells at the intersection of the selected WL and LDL are coupled through the selected GDL to the read amplifier 148, which provides the read data to the output circuit 122.

The memory bank logic region 140 also includes redundancy circuits 154 and 158. The redundancy circuits 154 and 158 are used as part of repair operations. If a row or column address has been repaired, the redundancy circuits 154 or 158 will direct access to a redundant word line or redundant column.

In an example write operation, data received along the DQ terminals is written to specified memory cells of the 3D memory device 100. The device 100 receives a row activation command along with a row address. The global row decoder 162 selects SWDs 172 to activate the associated word line based on the row address. The device 100 receives a write command along with a column address. Data is received by the input circuit 120 and deserialized by a buffer circuit 124 which provides the data to write amplifiers 146. The global column decoder 164 couples selected global digit lines to the GIO lines based on the column address YADD. In some embodiments, a multiplexer driver 176 is activated by the global row decoder 166 and couples a local digit line which intersects the active word line to the respective global digit lines. The data from the write amplifier 146 is written along the GIO lines to GDL line, onto the selected LDL lines and into the memory cells at the intersection of the LDL with the active word line WL.

In an example read operation, data from the array 180 is provided out along the DQ terminals. The device 100 receives a row activation command along with a row address. The global row decoder 162 selects SWDs 172 to activate the associated word line based on the row address. In some embodiments, the global row decoder 166 selects a multiplexer driver 176 to selectively couple one or more selected LDLs to the respective GDL. Data is read out from the memory cells which intersect the active word line through the intersecting LDLs and along the GDLs. The device 100 receives a read command along with a column address. Data is read out from selected ones of the GDLs along the GIO lines to a read amplifier 148. The read amplifier provides the read data to a buffer 126 which serializes the data and provides the serialized data to the output circuit 122.

The 3D memory device 100 may also perform refresh operations. As part of a refresh operation, one or more-word lines have the data in the intersecting memory cells refreshed. For example, the memory cells may store information as charge on a capacitive element, and that charge may decay over time. A refresh operation restores that charge to a nominal value. Responsive to a refresh command, a refresh control circuit 130 provides one or more refresh addresses RXADD which specify which word line or word lines should be refreshed.

FIG. 1 generally shows the 3D memory device 100 as a flattened 2D drawing. However certain components may be positioned over other components in an example implementation. For example, the bank logic circuits 140 may be positioned ‘above’ (in the z direction) the memory banks 180. For example, the sub-word line drivers 172 may be positioned above the staircase 182. In some embodiments, the memory device 100 may be printed on two chips, which are then bonded together. For example, components such as the array 180, staircase 182 and digit line multiplexers 184 may be printed in an array die, while the other components are printed on a CMOS die. A set of wafer to wafer (W2W) contacts 178 couple the CMOS die to the array die. In some embodiments, certain components may be positioned above the memory array. For example, at least some of the sense amplifiers 174 may be positioned above the array 180.

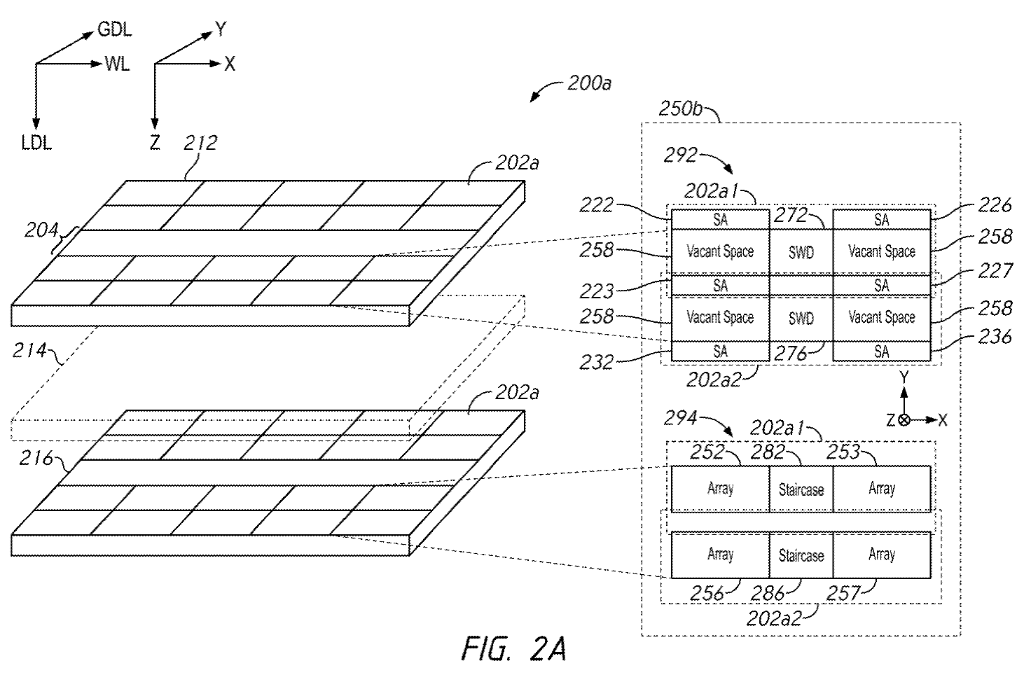

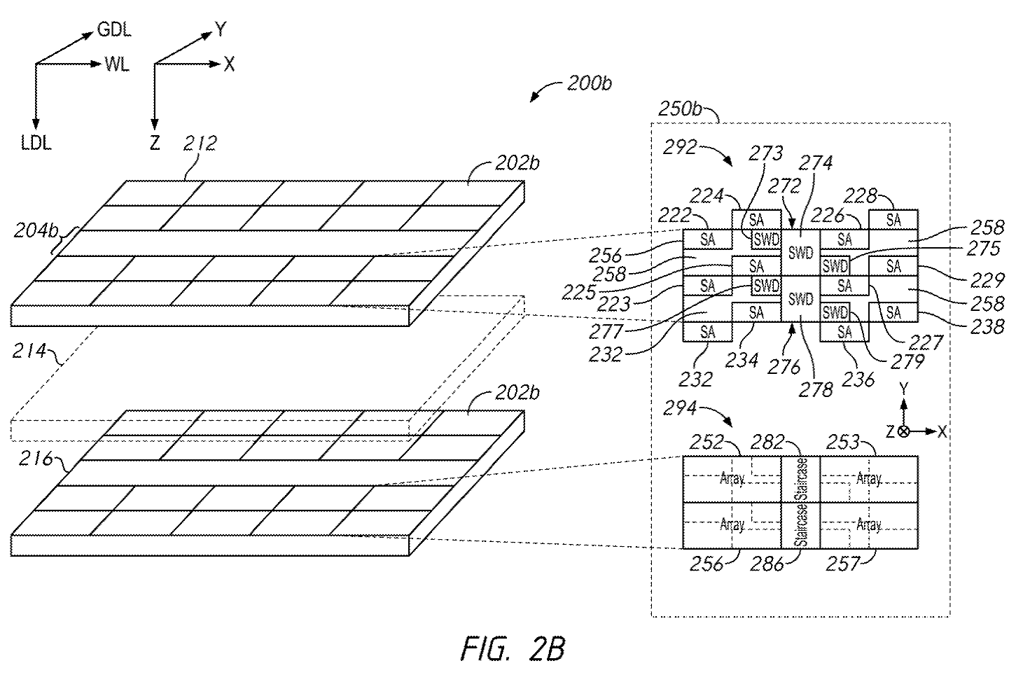

FIGS. 2A and 2B show example views of potential implementations of the memory device 100 of FIG. 1. FIG. 2A shows an embodiment where the circuits which support each array patch are positioned outside the area above the array patch. FIG. 2B shows an example implementation where certain circuit components are positioned ‘above’ the memory array patches.

FIG. 2A is a perspective drawing of a single die memory die with an inset showing a ‘top down’ view of two example memory sections according to some example embodiments of the present disclosure. The memory die 200a may, in some embodiments, represent a layout which implements the 3D memory device 100 of FIG. 1.

The memory die 200a includes a number of memory sections 202a, each of which includes one or more sections of memory array, such as memory patches, as well as circuitry which supports the operation of those patches such as SAs (e.g., 174 of FIG. 1) and SWDs (e.g., 172 of FIG. 1). The memory sections 202a are tiled in the x-y plane of the memory die 200a. The memory die 200a also includes a peripheral region 204, which does not have memory sections 202a tiled across it. The peripheral region 204 may include other circuits which are used in the operation of the memory such as the command circuit 114 of FIG. 1, the input and output circuits 116-122 of FIG. 1 and other components.

The memory device 200a is formed from two die, a first die 212 and a second die 216. The first die 212 is stacked on top of the second die 216 in the z-direction. The first die 212 may be a die which includes various circuits and components which operate the memory device 200b, while the second die 216 may be an array die which includes the memory cells, word lines, local digit lines and global digit lines. The second die 216 may also include components which are used to couple components together such as the staircase. The first die 212 may generally be referred to as a CMOS die and the second die 216 may generally be referred to as an array die.

The two die 212 and 216 may be bonded together. For example, wafer-to-wafer (W2W) bonding may be used. A bottom surface in the z direction of the first die 212 may have one or more connection points such as bumps. A top surface in the z direction of the second die 216 may have corresponding connection points such as bumps. When the two die are bonded, the connection points may be electrically coupled between corresponding bumps. In some embodiments, an optional bonding layer 214 between the two die may be used.

In the example of FIG. 2A, the peripheral region 204a extends across a width of the two die 212 and 216 in an x-direction, and a portion of the surface of the dice 212 and 216 in the y-direction. The peripheral region 204 is generally centered in the device along the y-axis. The device 200a has memory sections 202a positioned in a grid layout above in the +y direction and below in the -y direction the edges of the peripheral region 204. Other arrangements of the peripheral region 204 and sections 202a may be used in other example embodiments. FIG. 2A shows a simplified view with a 2x5 grid of sections 202a on either side of the peripheral region 204. However, more or fewer sections 202a, or different arrangements of sections 202a may generally be used in other example embodiments. For example, an implementation of a memory device may generally be expected to include many more sections 202a than the twenty sections illustrated in FIG. 2A.

Both die 212 and 216 have memory sections 202a which are tiled across the surface of the two die. Each memory section 202a has a portion on the first die 212 and a portion on the second die 216. The portions of a given memory section across the two die are vertically stacked so they align in an x-y plane and are stacked in the z direction.

The inset 250a shows a ‘top down’ view in the xy plane of two adjacent sections 202a1 and 202a2. The sections 202a1 and 202a2 represent examples of two of the sections 202a. The two sections 202a1 and 202a2 are adjacent to each other in the y direction. The inset 250a only shows two sections 202a1 and 202a2, however those sections may border other sections which are not shown in the inset 250a.

Each section 202a1 and 202a2 includes a pair of memory patches, four sense amplifier regions, and a sub word line driver and staircase region. Section 202a1 includes memory patches 252 and 253, SA regions 222, 226, 223, and 227, SWD region 272 and staircase region 282. The sense amplifier regions 222-227 and SWDs 272 are located in a first portion 292 on first die 212, while the staircase regions 282 and array patches 252-257 are located in a second portion 294 on the second die 214. Section 202a2 includes memory patches 256 and 257, SA regions 223, 227, 232, and 236, SWD region 276 and staircase region 286. The sense amplifier regions 223-236 and SWDs 276 are located in the first die 212 while the staircase regions 286 and array patches 256 and 257 are located in the second die 256.

The portion 292 includes spacer regions 258, located on either side of the SWD regions 272 and 276 and between the SA regions 222 and 223, and between the SA regions 226 and 227. These spacer regions are located above the memory array patches 252-257 in the z direction. The spacer regions 258 may be regions of the first die 212 which are generally empty of circuits in some embodiments.

The example layout of section 202a1 is described in detail. Since each section may be generally similar, the layout of section 202a2 is not described in detail. The section 202a1 includes a first array patch 252 and a second array patch 253. Patches 252 and 253 are generally elongated along the x axis and are generally longer along the x axis than they are tall along the y axis. Each patch 252 and 253 is also elongated along the z-axis, which is not shown in the ‘top down’ view of FIG. 2A. The staircase region 282 is positioned between the two array patches 252 and 253 such that the staircase region 282 separates the two patches 252 and 253 along the x axis. The staircase region 282 may be elongated in the x direction and may be longer in the x direction than it is tall in the y direction. In some embodiments, the height of the SWD and staircase region 282 in the y-axis may approximately match the height of the two adjacent array patches 252 and 253.

A SWD region 272 is positioned above the staircase region 282. The SWD region 272 may generally have the same x and y dimensions as the staircase region 282. Each spacer region 258 positioned above the array patches 252 and 253 is bordered by two sense amplifier regions positioned above and below the spacer regions 258 in the y-direction. For example, the SA region 222 is above in a +y direction the spacer 258 above the array patch 252 and the SA region 223 is below in a -y direction the spacer 258 above the array patch 252. Similarly, the SA region 226 is above spacer 258 above array patch 253 in a +y direction and the SA region 236 is below the spacer 258 above the array patch 253 in a -y direction. The SA regions 222-227 may generally be elongated in the x direction. The SA regions 222-227 may generally have the same length in the x-axis as the array patches 252 and 253 they are associated with. The SA region 222 is separated from the SA region 226 by a gap in the x direction, and the SA region 223 is separated from the SA region 227 by a gap in the x-direction. The gaps may be the width of the SWD region 272.

The memory array patches 252-257 represent a piece of the 3D array. For example, each memory patch 252-257 includes memory cells positioned at the intersection of word lines extending along the x axis and local digit lines extending in the z direction, which is into the plane of the page in the view of the inset 250a. The local digit lines are coupled together in columns running in the y direction by global digit lines.

The word lines in a section 202a1 or 202a2 extend continuously between the two array patches 252 and 253. For example, a word line may be continuous across the width of the array patch 252, through the staircase region 282 and across the width of the array patch 253. The word line intersects memory cells in the array patches, but not in the staircase region when passing underneath the SWDs. For example, a word line intersects local digit lines and memory cells in the array patch 252, then passes through the staircase region 282 without intersecting memory cells or LDLs and then intersects LDLs and memory cells again in the array patch 253. In other words, when considered along its length in the x direction, each word line has a gap where there are no coupled memory cells in the staircase region.

The SWD regions 272 and 276 include a number of SWDs, each of which is coupled to a respective word line which extends across both of the associated array sections 252/253 or 256/257 through the staircase region 282 and 286. For example, a first SWD in the region 272 is coupled to a first word line which extends across both array patches 252 and 253, a second SWD in the region 272 is coupled to a second word line which extends across both array patches 252 and 253, and so forth. The SWDs in the SWD region 272 or are arranged in a grid, which has dimensions based on the number and arrangement of word lines in the adjacent memory patches 252/253 or 256/257. For example, if there are M word lines in the y-direction and N word lines in the z direction across the two patches 252/253 or 256/257 for a total of NxM word lines in each section 202a1 or 202a2, then there will also be NxM SWDs in the region 272 or 276. For example, the region 272 may have a grid of SWDs with M SWDs in the y-direction and N SWDs in the x direction. Along a given row in the x direction, each SWD couples to a different depth of word line in the z-direction using a connective element which extends along the z-direction to the associated word line.

The sense amplifier regions 222-236 each include a number of sense amplifiers, each of which is coupled to a respective global digit line in the associated array sections 252-257 below the spacer regions 258 that the sense amplifier region 222-236 is adjacent to. In the implementation of FIG. 2A, the sense amplifiers in a region 222-236 may generally couple to alternate global digit lines. For example, the sense amplifiers in the region 262 may couple to ‘even’ global digit lines in the array section 252, while the sense amplifiers in the region 264 may couple to ‘odd’ global digit lines in the array section 252.

The two sections 202a1 and 202a2 may share components. For example, the sense amplifier regions 223 and 227 include sense amplifiers which are coupled to global digit lines in both of the memory patches 252 and 256 under the spacer regions 258 adjacent to those sense amplifier regions 223 and 227. For example, the sense amplifier region 223 is coupled to global digit lines in both array sections 252 and 256 and the sense amplifier region 227 is coupled to global digit lines in both array patches 253 and 257. In an example implementation, the sense amplifiers in the region 223 may couple to odd global digit lines in both of the array patches 252 and 256. Similarly, the sense amplifiers 222 may couple to even global digit lines in the array section 252 and a different array patch adjacent on the other side, not shown in the inset 250a. The sections 202a which are on the edge of the die 200a with no adjacent section in the y-direction may have a region of sense amplifiers which are not shared, but instead only couple to global digit lines in the one adjacent patch.

In an example implementation, each of the memory patches 252-257 may include about 8Mbit of storage or about 8,192,000 memory cells. An example memory patch 252 has 8000-word lines arranged in a grid in the yz plane of80-word lines in the y direction and 100-word lines in the z direction. Each associated sense amplifier region 222 and 223 includes about 512 sense amplifiers coupled to half of the global digit lines which cross the array patch 252, for a total of 1024 global digit lines in the memory patch 252. The SWD region 272 includes 8000 SWDs, one for each word line, arranged in a grid in the xy plane of 80 SWDs in the y direction and 100 in the x direction.

FIG. 2B is a perspective drawing of a memory device where circuit elements are placed over the memory patches, with a inset showing a ‘top down’ view of two example memory sections according to some example embodiments of the present disclosure. The memory device 200b may, in some embodiments represent a layout which implements the 3D memory device 100 of FIG. 1. The memory device 200b may be generally similar to the memory device 200a, except that in the memory device 200b, the layout of the sections 202b are different than the layout of the sections 202a of FIG. 2A. In particular, the sections 202b are laid out with portions of the sense amplifiers and SWDs positioned over the array patches.

Since the memory device 200b may generally be similar to the memory device 200a, for the sake of brevity details and components already described with respect to FIG. 2A will not be repeated again with respect to FIG. 2B.

The memory device 200b is laid out in a manner similar to the memory device 200a with a peripheral region 204 and sections 202b, each of which has portions in the first die 212 and the second die 216. The inset 250b shows two example sections 202b, split into a portion 292 in the first die 212 and a portion 294 in the second die 216. The first portion 292 and the second portion 294 may generally be vertically aligned with each other, with the spacer regions 258 aligned over the array patches 252-257.

The portion 294 has dotted lines on the array patches 252-257 to represent the portions of the array patches 252-257 which have circuit elements above them (in the z-direction). Since the elements in the portion 292 are in a different die than the elements in the portion 294, the circuit elements can occupy overlapping regions of space in the xy plane with the array patches 252-257 without interfering with the operation or layout of the patches 252-257. By moving components in the first die 212 over the array patches, the overall xy dimensions of the section 202b may be reduced compared to the section 202a while maintaining a same number of memory cells per section. This may allow a reduction in the overall size of the die 200b compared to 200a and/or an increase in the amount of storage (e.g., the number of memory cells) on the die 200a compared to the die 200b.

In the sections 202b, the sense amplifiers 222-238 are positioned over one of the two memory patches they are associated with. Each sense amplifier region may be separated into two portions, one of which is over one of the two patches that region is associated with and the other of which is over the other of the two patches that region is associated with. For example, the sense amplifier region associated with the patches 252 and 256 is divided into two portions 223 and 225. The portion 223 is positioned above the array patch 256 and the portion 225 is positioned above the array patch 252. For example, compared to an interpatch region which runs along the border between the two patches 252 and 256 and the two spacer regions 258 above them, the sense amplifier portion 223 is displaced in a -y direction from the interpatch region while the sense amplifier portion 225 is displaced in a +y direction from the interpatch region. In other words, using ‘upper’ and ‘lower’ to refer to the +y and -y directions for this example, the upper edge of the sense amplifier region 223 is along the interpatch region while the lower edge of the sense amplifier region 226 is along the interpatch region.

The GDLs may run through the array patches in the y direction to the interpatch region, where they have vertical elements extending in the z direction from the interpatch region in the die 216 to the interpatch region in the die 212. In the die 212 they couple to horizontal elements running in the y direction which couple them to the associated sense amplifier portion.

The two portions may divide the sense amplifier region in half. For example, if there are 512 sense amplifiers for each region, then each sense amplifier portion 222-238 includes 256 sense amplifiers. In other words, a first half of the even or odd digit lines may couple to a first sense amplifier portion while a second half of the even or odd digit lines may couple to a second sense amplifier portion. For example considering the patch 252, a first half of the even GDLs couple to the portion 222, a second half of the even GDLs couple to the portion 224, a first half of the odd digit lines couple to the portion 223, and a second half of the odd digit lines couple to the portion 225. The portions 222 and 225 are above the memory patch 252, but the portions 224 and 223 are not above the patch 225 but are above adjacent patches instead. In this manner, in a given patch the first half of the GDLs digit lines have one of even or odd GDLs coupled to sense amplifiers which are over the patch while the other of the even or odd GDLs are coupled to sense amplifiers which are not over the patch and the second half of the GDLS have the other of even or odd GDLs coupled to sense amplifiers which are over the patch while the one of the even or odd GDLs are coupled to sense amplifiers which are not over the patch.

In the example of FIGS. 2B, some of the SWDs are also positioned above the patches 252-257. For example, each SWD region 272 and 276 may be divided into a central region which is between the two associated patches, and side portions which are each above a respective one of the associated portions. For example, the SWD region 272 includes a central portion 274, a first side portion 273 which is above patch 252 and a second side portion 275 which is above patch 253. The SWD region 276 includes a central portion 278, a first portion 277 which is above the first which is above the patch 256 and a second portion 279 which is above the patch 257. The two portions which are above the patches may be aligned with different edges of the central portion. For example, the portion 273 has a top edge (in the y direction) aligned with the top edge (in the y direction) of the central portion 274, while the portion 275 has a lower edge (in the y direction) aligned with the lower edge (in the y direction) of the central portion 274. In some embodiments, the portions which are over the array patch may be smaller than the central portion which is over the staircase region.

The SWDs which are in the portions above the patch 252-257 may still connect to the word line through the staircase region. For example, each of the SWDs in the SWD region 272 may be coupled to their respective WLs by vertical conductive elements which run in the z direction in the staircase region 282. The SWDs in the central portion 274 which is above the staircase region 282 may be coupled directly to the vertical conductive elements. The SWDs in the regions 273 and 275 are coupled by horizontal conductive elements in the x direction.

In some example embodiments, like the layout sown in FIG. 2B, both sense amplifiers and SWDs may be positioned over the patches. In some example embodiments, the sense amplifiers 222-238 may be positioned over the array, but the SWDs may be in a central region between the patches similar to FIG. 2A. In some example embodiments, some of the SWDs may be over the patches, but the sense amplifiers may be positioned in the interpatch region similar to FIG. 2A.

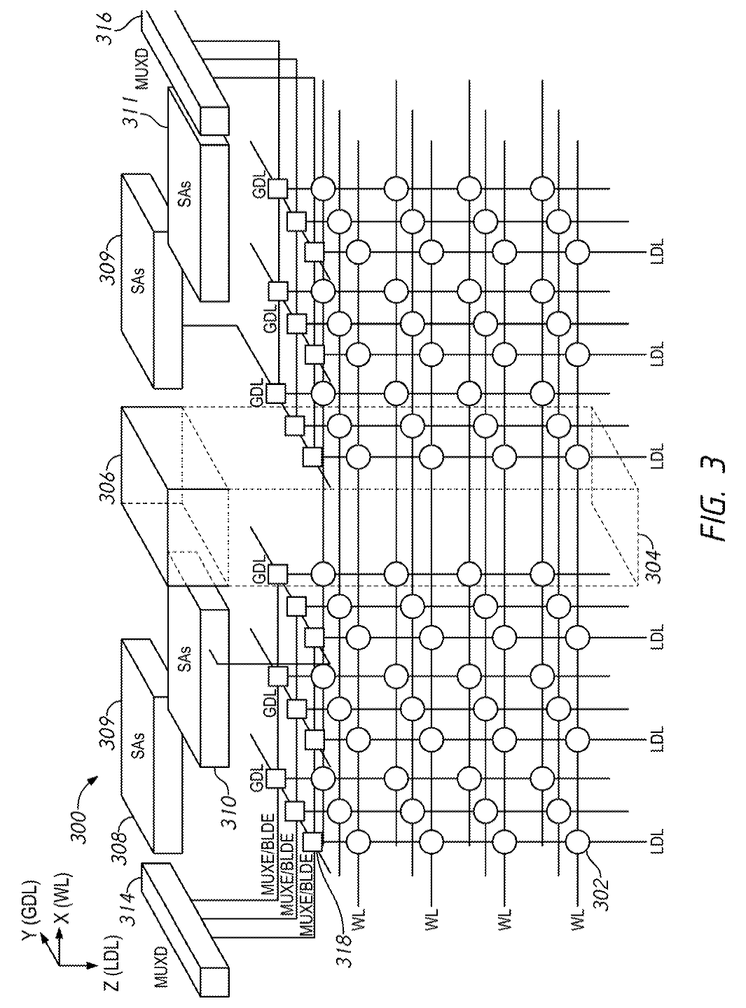

FIG. 3 is a perspective schematic diagram of a portion of a 3D memory array according to some embodiments of the present disclosure. The 3D memory array 300 represents a simplified view of an example portion of a memory array. For example, the 3D memory array 300 may represent a portion of the 3D array 180 of FIG. 1, and/or 252-257 of FIGS. 2A and 2B. The perspective of FIG. 3B shows an example set of memory cells 302 and their respective word lines, local digit lines and global digit lines.

The memory array 300 shows memory cells 302. Each memory cell 302 is positioned at the intersection of a word line WL and a local digit line LDL. The LDLs are coupled together by global digit lines GDL. The global digit lines are coupled to respective sense amplifiers in sense amplifier portions 308-311 (e.g., 174 of FIG. 1 and/or 262-267 of FIGS. 2A-2B). The word lines are each coupled to a respective SWD in a SWD region 306 (e.g., 172 of FIG. 1 and/or 272-276 of FIGS. 2A-2B). The word lines are coupled via a staircase region 304 (e.g., 182 of FIG. 1, 272-276 of FIG. 2A, and/or 282-284 of FIG. 2B) to the SWD region 306.

In some embodiments the SA regions 308-311 and SWD region 306 may be in a different die than the die which includes the WL, LDL, GDL, and memory cells 302. The view of FIG. 3 shows an example embodiment similar to the embodiment of FIG. 2B, where the sense amplifier regions 308-311 are positioned above the array patches. In the view of FIG. 3, only the sense amplifier regions which are positioned above the patches are shown. Some of the GDLs will couple to sense amplifiers in SA regions positioned above adjacent memory patches, which are not shown in FIG. 3.

The staircase region 304 is a 3D region, which may be generally have the form of a rectangular prism. The staircase region 304 is positioned underneath the SWD region 306 in the z-direction. In some embodiments, the staircase region 304 may have the same x-y dimensions as the SWD region 306. The staircase region 304 is positioned between two sections of the word lines WL which intersect memory cells 302. However, the WLs may not intersect any memory cells while they pass through the staircase region 304. Vertical connection elements which extend in the z direction (not shown in FIG. 3) couple each word line to a respective SWD in the SWD region 306. A middle of the word lines WL may be positioned in the staircase region 304.

The word lines WL are arranged in a grid when considered in the yz plane. Similarly, the LDLs may be arranged in a grid when considered in the xy plane. The GDLs are generally arranged in a plane side-by-side with each other.

The LDLs are selectively coupled to the associated GDL through a multiplexer circuit 318. The multiplexers are coupled to multiplexer drivers in a multiplexer driver region 314 or 316. A line of multiplexer drivers may be coupled in common by a multiplexer driver line along the x direction to a multiplexer driver in the multiplexer driver region 314/316. The multiplexer driver provides a multiplexer enable signal MUXE. When MUXE is active, all the multiplexers 318 which are coupled in common to that signal line will couple their respective LDL to the associated GDL.

In some embodiments, the multiplexer drivers may also provide a bleed enable signal BLDE. When the bleed enable signal BLDE is active, the multiplexer couples the respective LDL to a ground voltage. In an example operation, the multiplexer driver associated with the row address provides an active MUXE signal and an inactive BLDE signal while the multiplexer drivers which are not associated with the row address provide an active BLDE signal and an inactive MUXE signal. Accordingly, during the operation, multiplexers which receive an active MUXE couple their LDLs to the GDL, while the other multiplexers along each GDL isolate their LDLs from the GDL and instead couple them to a ground voltage so they do not float.

In some embodiments, the decoded row address may be provided multiplexer driver regions, such as 314 and 316, in adjacent memory sections (not shown in FIG. 3). Specifically, the sections which are adjacent in the +y and -y directions from the section 300. Those multiplexer drivers may also selectively couple LDLs in those sections to the respective GDLs. The sense amplifiers in the regions 308-311 may be coupled to GDLs in those sections. In this way, the capacitance along both GDLs coupled to the SA may match, because the total length of the coupled signal lines may match.

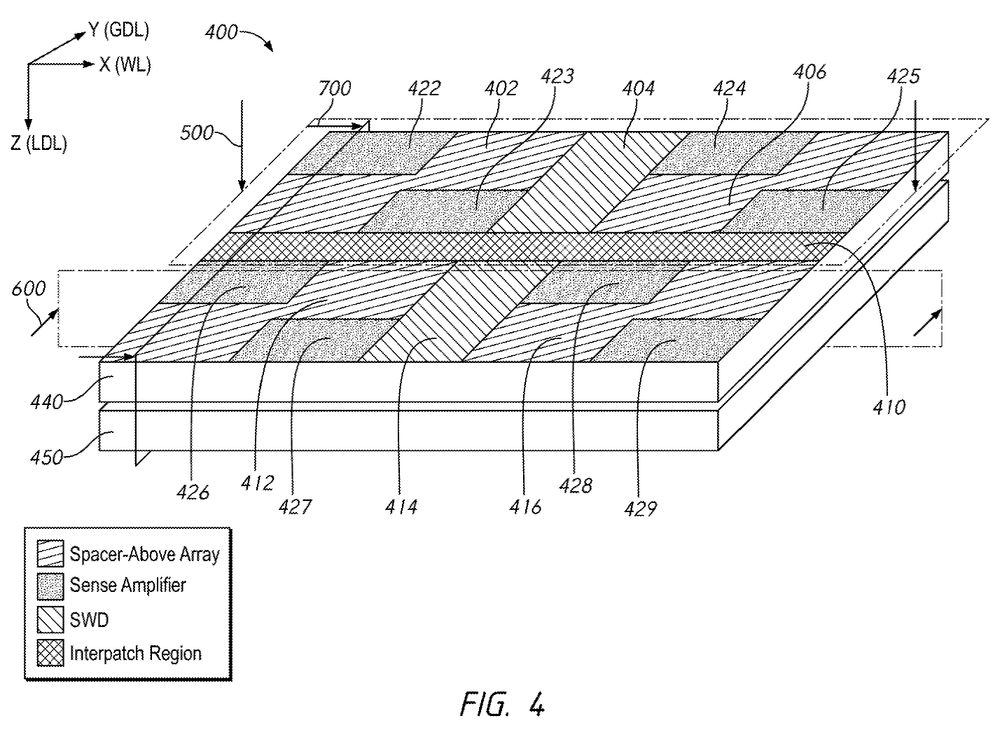

FIG. 4 is a perspective view of a portion of a memory device according to some embodiments of the present disclosure. The memory device 400 may represent a portion of a memory device such as 100 of FIG. 1, 200a of FIG. 2A and/or 200b of FIG. 2B. The memory device 400 may include a memory array similar to the layout of the memory array 300 of FIG. 3 in some embodiments. The memory device 400 shows two adjacent sections of a memory array, similar to the view of the insets 250a and 250b of FIGS. 2A-2B. However, FIG. 4 shows a perspective view rather than a ‘top down’ view of the xy plane.

The memory device 400 includes a first die 440 (e.g., 212 of FIG. 2) and a second die 450 (e.g., 216 of FIG. 2). The first die 440 may includes the sense amplifiers, SWDs, and multiplexer drivers. For example, the first die 440 may be a CMOS die. The second die 450 includes the memory array patches.

The memory device 400 includes a first section which includes a first memory patch 402, a second memory patch 406 and a SWD region 404 in between. The memory device also includes a second section which includes a third memory patch 412, a fourth memory patch 416 and a second SWD region 414 in between. An interpatch region 410 is between the patches 402 and 412 and the patches 406 and 416. In the perspective view of FIG. 4, spacer regions are shown on the surface of the first die 440 which are above the memory patches in the array die 450 below.

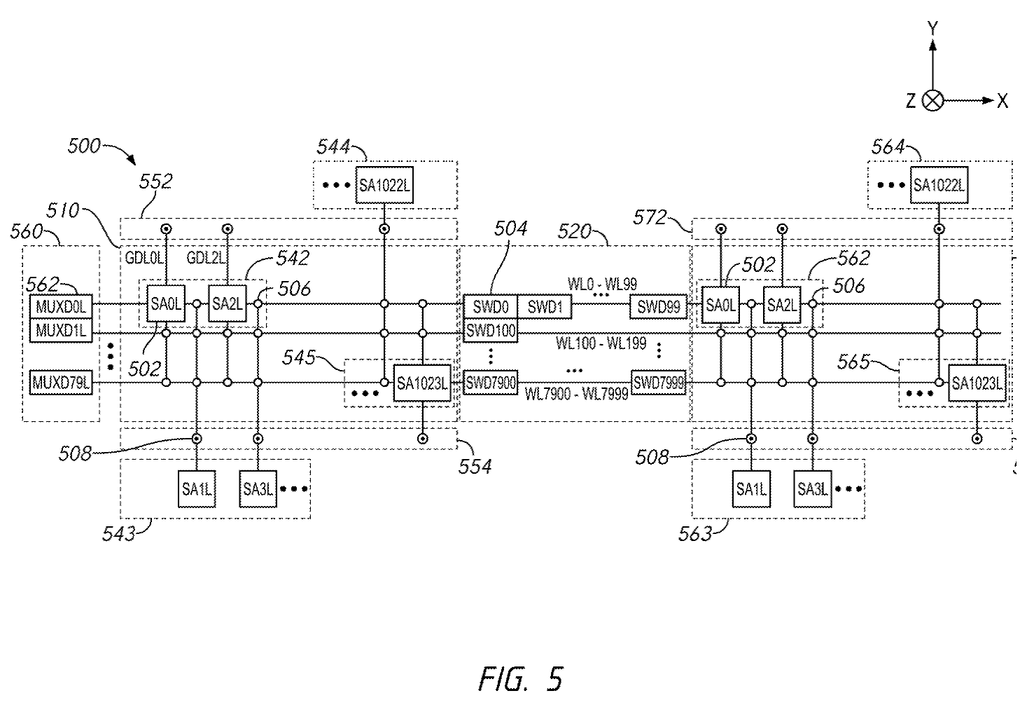

FIG. 4 shows planes 500, 600, and 700 which represent the cross-sectional views of FIGS. 5, 6, and 7 respectively. The plane 500 is a slice along an xy plane of the memory 400 which intersects a first patch 402 (e.g., 252 of FIGS. 2A-2B), a SWD region 404 (e.g., 272 and 282 of FIGS. 2A-2B), a second memory patch 406 (e.g., 253 of FIGS. 2A-2B), and the sense amplifier regions 420-425 (e.g., 262-267 of FIGS. 2A-2B). Also shown in the view of the plane 500 are the interpatch region 410 as well as additional regions associated with the two patches 402 and 406 such as the SA regions 426 and 428 and an additional interpatch region and additional SA regions not shown in FIG. 4 which are above the patches 402 and 406 in the y direction.

The plane 600 is a slice along an xz plane of the memory which intersects a second memory patch 412, an SWD and staircase region 414 and a second memory patch 416. The plane 700 is a slice along a yz plane which intersects the first memory patch 402, interpatch region 410, and the third memory patch 412. The view 700 also intersects sense amplifier regions 426 and 422 which are above the patches 412 and 402 respectively.

FIGS. 5-7 show different cross-sectional views of the memory device 400 of FIG. 4. Each of FIGS. 5-7 is illustrated with respect to an example embodiment where each memory patch such as 402, 406 or 408 includes 8 Mbit of memory cells. Specifically, they are shown to include a grid of 80-word lines in the y direction and 100-word lines in the z direction, a grid of 80 LDLs in the y direction and 1024 LDLs in the x direction, and 1024 global digit lines side-by-side. This arrangement is shown as an illustrative example only. Other numbers and/or arrangements of word lines, global digit lines, local digit lines, memory cells, sense amplifiers, and so forth may be used in other example embodiments.

FIG. 5 is a cross sectional view of a memory device according to some embodiments of the present disclosure. The cross section 500 shows the plane 500 of FIG. 4. The cross section 500 represents a view along an example xy plane, showing a top layer of word lines extending horizontally in an x direction, global digit lines extending in a y direction, and local digit lines extending into the plane of the page in the z direction from the multiplexer circuits 506 where they intersect the GDL. The view of FIG. 5 shows a slice of the ‘top’ word lines in a stack of word lines, with additional word line extending down in the z direction. The cross sectional view of FIG. 5 shows a view of components which are not contained within a single plane. For example, the SWDs 504 and sense amplifiers 502 may generally be located in a plane which is above the plane of the word line in the z direction. Certain components in the plane of the array, such as certain multiplexers 506 may be occluded by the sense amplifiers which are above the memory patch.

The cross section 500 shows a first memory patch 510 (e.g., 252 of FIGS. 2A-2B and/or 402 of FIG. 4), a SWD and staircase region 520 (e.g., 272 of FIGS. 2A-2B and/or 404 of FIG. 4), and a second memory patch (e.g., 253 of FIGS. 2A-2B and/or 406 of FIG. 4). Also shown are sense amplifier regions 542-549 (e.g., 222-238 of FIGS. 2A-2B and/or 308-311 of FIG. 3). The view of FIG. 5 may represent a single memory section (e.g., 202a of FIG. 2A and/or 202b of FIG. 2B). In particular, the view of FIG. 5 may be similar to the layout of FIG. 2B, where the sense amplifier regions are positioned over the array. The first memory patch 510 and the second memory patch 520 are located on opposite sides of the SWD and staircase region 520 in the x direction.

The sense amplifier portions 542-545 are associated with the first patch 510. The sense amplifier portions 562-565 are associated with the second patch 520. The portions 542 and 544 form a first region and are associated with even GDLs. The portions 543 and 545 form a second region and are associated with odd GDLs. Similarly, the portions 562/564 couple to even GDLs and the portions 563/565 couple to even GDLs. The portions 542, 545, 562, and 565 are located above the memory patches 510 and 530 respectively. The portions 543, 546, 563, and 566 are located above patches which are adjacent (in the y direction) from the patches 510 and 530.

Interpatch regions 552, 554, 572 and 574 form a border between the array patches 510 and 520 and adjacent patches in the y directions, not shown in FIG. 5. For example, the interpatch region 552 is between the patch 510 and another patch which is above it in the +y direction and the interpatch region 554 is between the patch 510 and another patch which is below it in the -y direction. Within the interpatch region, vertical elements 508 couple the GDLs from the die where the array is located to the die where the SAs 502 are located.

The cross section 500 includes word lines WL0 to WL7999. The word lines are arranged in 80 stacks of 100-word lines each. So, the top row of word lines includes the visible word line (WL0) as well as 99 more word lines extending in the z direction into the plane from the point of view of the drawing. Multiplexer circuits couple a ‘top’ of one or more LDLs to associated GDLs. The LDLs are arranged in a grid layout in an xy plane, with a row of the grid including 1024 LDLs along the x direction and a column of the grid including of 80 LDLs along the y direction. The word lines WL extend from the first patch 510 to the second patch 530 under the SWD and staircase region 520.

The SWD and staircase region 520 includes a number of SWDs 504. There is a SWD for each word line. In this example there are 8000 SWD, arranged in a grid of 80x100 SWDs in the yz plane. The SWDs 504 are arranged in 80 rows, with each row over a stack of WLs. Since the stacks of WLs are arranged with 100 WLs in each stack, each row of SWDs has 100 SWDs. Each SWD along a row has a conductive element running in the z direction down to the WL it is coupled to. The SWDs along a ‘row’ of the grid of SWDs are coupled to conductive elements of different lengths, since they are coupled to different depths (in the z direction) of word line. When activated by a row activation command, the SWD associated with the row address activates the associated word line.

The global digit lines in each patch 510 and 530 are alternately coupled to different sense amplifier portions. A first half of the GDLs in a patch are coupled either to a first portion or a second portion, and a second half of the GDLs in a patch are coupled either to a third portion or a fourth portion. For each half of the GDLs, either the even or odd GDLs are coupled to a portion which is over the patch or over an adjacent patch and whether it is the even or odds is reversed in the other half.

For example, in patch 510, the even GDLs from GDL0 to GDL510 are coupled to SA circuits 502 in the portion 542, while the odd GDLs from GDL1 to GDL511 are coupled to SA circuits 502 in the portion 543. Similarly, the even GDLs from GDL512 to GDL1022 are coupled to SA circuits 502 in the portion 544 while the odd GDLs from GDL513 to GDL1023 are coupled to SA circuits 502 in the portion 545. The even GDLs GLD0 to GDL1022 are coupled to sense amplifier circuits 502 through the first interpatch region 552, while the odd GDLs GDL1 to GDL1023 are coupled to sense amplifier circuits 502 through the second interpatch region 554.

The sense amplifier regions 542-545 and 562-565 are offset relative to the interpatch region they are associated. The sense amplifier portion 542 is below the interpatch region 552 in the y direction while the sense amplifier portion 544 is above the interpatch region 552 in the y direction. Similarly, the sense amplifier portion 543 is below the interpatch region 554 in the y direction while the sense amplifier portion 545 is above the interpatch region 554 in the y direction. Because of this the sense amplifiers are coupled to the vertical conductive elements 508 by horizontal elements which couple from a ‘top’ of the vertical conductive element 508 over to the sense amplifier.

The LDLs are coupled to the GDL by a multiplexer circuit 506. The multiplexer circuit is generally positioned between a ‘top’ of the LDL in the z direction and the GDL. In the embodiment of FIG. 5, there is a multiplexer circuit 506 for each LDL. Other example embodiments may group multiple LDLs together through each multiplexer circuit 506. A multiplexer driver circuit 562 is coupled by one or more signal lines extending in the x direction to a row of multiplexer driver circuits. The signal lines provide multiplexer enable signals, bleed enable signals or both. A row of multiplexers 506 may be coupled to a multiplexer driver in common.

In the embodiment of FIG. 5, the multiplexers 506 are arranged in an xy grid of 80 rows and 1024 columns. Each row of 1024 multiplexers is coupled in common to a multiplexer driver 562 in a multiplexer driver region 560. Accordingly, there are 80 multiplexer drivers 562. Responsive to a row address, one of the multiplexer drivers 562 may activate the multiplexers 506 along the associated row, while the other multiplexer drivers remain inactive (and/or provide the bleed signal at an active level). The active multiplexer driver is the one in the same row as the word line. For example, if one of the word lines WL0 to WL99 is activated, then the first multiplexer driver MUXD0 will be activated.

When a row activation command is received along with a row address, the SWD 504 associated with that address activates the associated word line. The associated multiplexer driver 562 activates the multiplexer circuit 506 so that the LDLs which intersect the active word line are coupled to the respective GDLs. When the word line is activated, the memory cells along that word line are coupled to the intersecting LDL 506 and change a voltage of the LDL and the GDL that LDL is coupled to based on the stored charge. The SA coupled to that GDL senses this change and amplifies it during a read operation or drives a new value onto the GDL in a write operation.

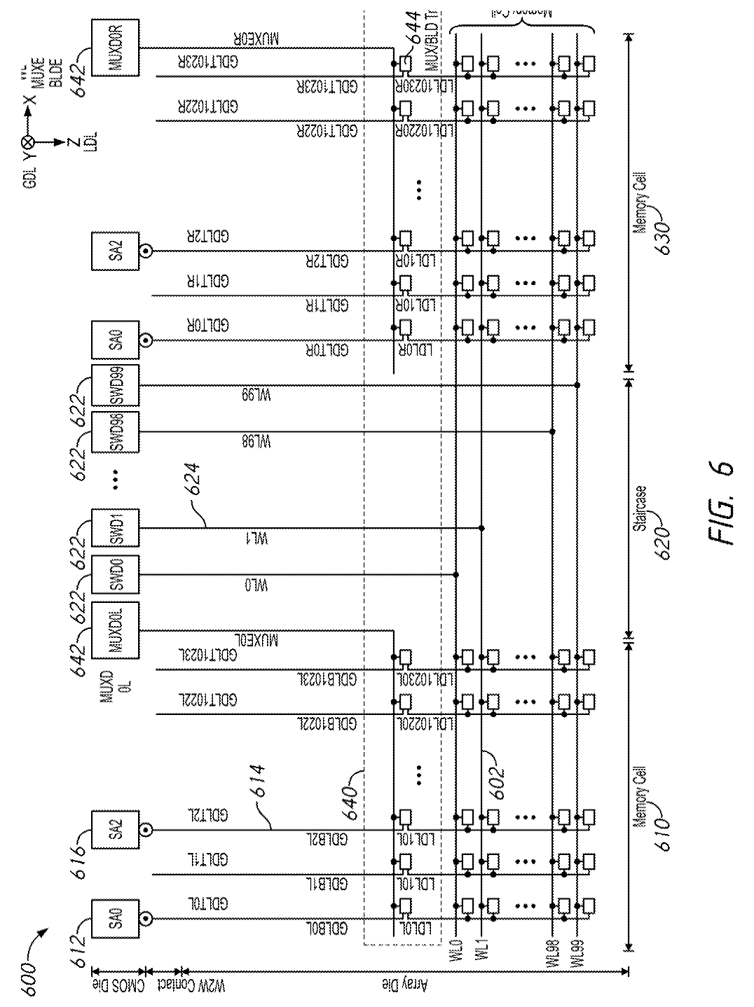

FIG. 6 is a cross-sectional view of a memory device according to some embodiments of the present disclosure. The cross section 600 shows the plane 600 of FIG. 4. The cross section 600 represents a view along an example xz plane, showing word lines running horizontally along the x direction, local digit lines running vertically along a z direction, and global digit lines running into and out of the plane of the page along a y direction. A vertical conductive element 614 is shown in an interpatch region (e.g., 410 of FIG. 4) which runs ‘behind’ the plane of the cross section 600. The vertical conductive element 614 is coupled to a horizontal element 616 which couples to the sense amplifiers 612, which are positioned over the memory cells. The sense amplifiers 612 shown are the ones in the portions which couple to even digit lines for example the ones in regions 426 and 428 of FIG. 4.

The cross section 600 shows a first memory patch 610 (e.g., 252 of FIGS. 2A-2B 402 of FIG. 4, and/or 510 of FIG. 5), a staircase region 620 (e.g., 272 of FIGS. 2A-2B, 404 of FIG. 4, and/or 520 of FIG. 5), and a second memory patch 630 (e.g., 253 of FIGS. 2A-2B 406 of FIG. 4, and/or 530 of FIG. 5). The cross section 600 also shows a row a SWDs 622 associated with the WLs.

Each word line is coupled to a respective SWD 622. For example, the cross section 600 shows SWD0 to SWD99, which are associated with WL0 to WL99 respectively. The SWDs 622 are located above in the z direction a staircase region 620 which is between the two patches 610 and 630 in the x direction. Each SWD 622 is coupled to a vertical conductive element 624 which extends in the z direction to the associated word line. Along a row of SWDs 622 like the one shown in FIG. 6, each of these vertical conductive elements 624 may be a different length, since the WLs are at different depths in the z direction. In the example layout of FIG. 6, the shortest vertical conductive element, coupled to the ‘top’ word line WL0, is on the far left, while the longest vertical conductive element, coupled to the ‘bottom’ word line WL99, is on the far right. Other arrangements may be used in other example embodiments.

The cross section 600 shows a ‘stack’ of word lines. In this case the word lines WL0 to WL99. A number of LDLs extend vertically in the z direction and memory cells 502 are coupled at the intersection of the LDLs and the WLs. In the example implementation, there are 81,920 LDLs per patch from LDL0 to LDL81919. Each LDL seen in the cross section 600 represents a ‘top’ of a stack of 80 LDLs which extend in the y direction. Thus the leftmost LDL in the patch 610 is LDL0L, the next LDL is LDL80L, the next is LDL160L and so forth up to LDL81840L. Similarly, the LDLs in the patch 620 are LDL0R up to LDL81919R.

The view of FIG. 6 includes digit line multiplexers 644 (e.g., 184 of FIG. 1) in a digit line multiplexer region 640, and example multiplexer drivers 642. The multiplexers 644 selectively couple a set of LDLs to the respective GDLs. In the xz slice shown in FIG. 6, the multiplexers 644 of the left patch 610 are coupled to a multiplexer driver 642 and the multiplexers 644 of the right patch 630 are coupled to a multiplexer driver 642. The multiplexer drivers 642 are coupled along signal lines which extend in the x direction the multiplexer circuits 644. For example, a first signal line couples the multiplexers 644 in the patch 610 to the driver 642 and a second signal line couples the multiplexers 644 in the patch 630 to the driver 642. The multiplexer drivers 642 and signal line represent a single row. Additional rows are stacked in the y direction in and out of the plane of the page.

Responsive to a row activation command and a row address, the SWD 622 specified by the row address activates the coupled word line along the respective vertical conductive element 624. This couples the memory cells 602 in the two patches 610 and 630 to be coupled to the LDLs which intersect that word line. Responsive to a signal from a global row decoder (e.g., 166 of FIG. 1) based on the row address, the multiplexer drivers 642 activate the multiplexers 644 to couple the LDLs along the cross section 600 to their respective GDLs. The memory cells along the activated WL drive a voltage onto the intersecting LDLs, which then drive a voltage to the coupled GDL through the activated multiplexers 644. The other LDLs, which are stacked in the Y direction and not visible in FIG. 6, are coupled to multiplexers which are coupled to different multiplexer drivers, and thus are not coupled to the GDLs. This may help reduce the capacitance of the GDL since each GDL is only coupled to one LDL at a time.

In some embodiments, the SWDs 622 and multiplexer drivers 642 may be located in a CMOS die (e.g., 212 of FIG. 2B) while the memory cells, LDLs, WLs, and, if used multiplexer region 640 are located in an array die (e.g., 216 of FIG. 2B). The vertical elements 624, as well as the vertical portions of the GDLs may extend from the array die to the CMOS die and may include contacts between the two dice not shown in FIG. 6.

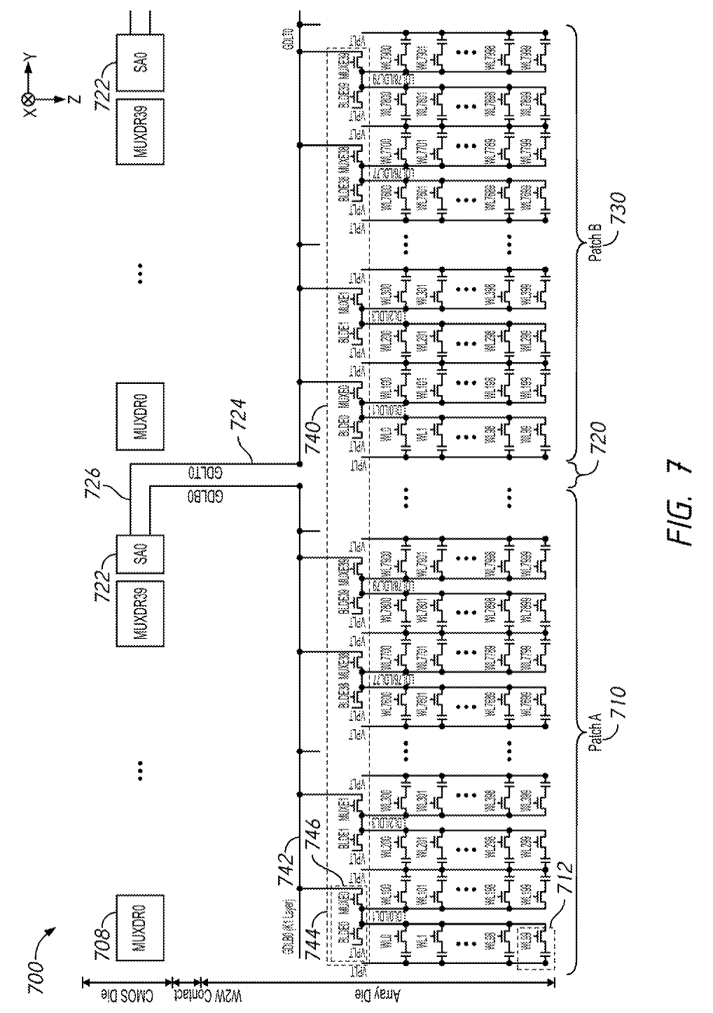

FIG. 7 is a cross-sectional view of a memory device according to some embodiments of the present disclosure. The cross section 700 shows the plane 700 of FIG. 7. The cross section 700 represents a view along an example yz plane, showing two global digit lines running horizontally in the y direction, local digit lines running vertically in the z direction, and word lines running through the plane of the page in the x direction. The cross section 700 shows a first memory patch 710 (e.g., 252 of FIGS. 2A-2B 402 of FIG. 4 510 of FIG. 5, and/or 610 of FIG. 6), an interpatch region 720 (e.g., 410 of FIG. 4), and a second memory patch 730 (e.g., 256 of FIGS. 2A-2B, and/or 408 of FIG. 4).

The cross section 700 intersects 8000-word lines in each memory patch 710 and 730. The word lines are organized in a grid in the yz plane with eighty columns in the z direction that have 100-word lines each. Accordingly, the cross section shows 16,000 memory cells 712, 8000 in each patch 710 and 730, with each patch organized in a grid of 80 memory cells in the x direction and 100 memory cells in the z direction. Each column of memory cells 712 is coupled to a local digit line, here labelled LDL0 to LDL79. In the embodiment of FIG. 7, the LDLs are paired and each pair LDLs is coupled in common to a multiplexer circuit 746 as described in more detail herein. In some embodiments, each LDL may couple separately through a multiplexer to the GDL, rather than being paired.

Each memory cell 712 includes a capacitive element and a transistor. The gate of the transistor is coupled to the word line. One side of the capacitive element is coupled to a plate voltage VPLT, and the other side is coupled through the transistor to the LDL. When the word line is activated, the SWD drives a voltage along the word line which activates the transistor, coupling the capacitive element to the LDL.

The cross section 700 shows a sense amplifier 722. The sense amplifier 722 is labelled as SA0 because it is coupled to GDL0 in two adjacent patches 710 and 730. To distinguish them, those GDLs are labelled as GDLB0 in the first patch 710 and GDLT0 in the second patch 730. During an example operation, one of the two GDLs is used to carry information, and the other is used as a reference. For example, if a word line is activated in the first patch 710, then information is carried along GDLB0 and GDLT0 is used as a reference. During a read operation, the sense amplifier senses a difference between the GDL with information and the reference and then amplifies that difference. During a write operation, the sense amplifier drives one GDL to a voltage representing the write value and the other to the compliment of the write value.

The sense amplifier 722 is shown positioned above the memory patch 710. Vertical conductive elements 724 in the interpatch region 720 couple the GLDs GDLB0 and GDLT0 up from the array die to the CMOS die. Horizontal conductive elements 726 couple the vertical conductive elements from the interpatch region 720 to the location of the sense amplifier 722 over the array patch 710. Another sense amplifier is shown over the patch 730 as an example, however that sense amplifier may be in a different plane offset in the x direction and is coupled to GDLT1 and a GDLB1 from an adjacent patch (in the +y direction) not shown in FIG. 7.

FIG. 7 shows multiplexer region 740 along with the multiplexer drivers 708 which operates the multiplexer region. The multiplexer circuits 746 are implemented by a multiplexer transistor 742 and an optional bleed transistor 744. Each pair of LDLs is coupled to the GDL through a multiplexer transistor 742. The gate of the multiplexer transistor 742 is coupled to a multiplexer control signal MUXE which is coupled to respective multiplexer drivers 708 along a signal line which runs in the x direction. The bleed transistor 744 selectively couples each pair of LDL to the plate voltage VPLT. The bleed transistors 744 have gates coupled to bleed control signals BLDE which are coupled to respective multiplexer drivers 708 along signal lines which run in the x direction. The multiplexer drivers 708 are controlled by global row decoders (e.g., 166 of FIG. 1).

During an example operation, if a row address is received associated with the first patch 710, then the multiplexer driver 708 which controls the LDL which intersects the WL activates the multiplexer transistor 742 by providing MUXE, and each of the other multiplexer drivers 708 provide BLDE to their respective bleed transistor 744 to couple those LDLs to VPLT and prevent them from floating. For example, if the row address indicates WL 101, which intersects LDL1, then MUXD0 provides MUXE0, which couples both LDL0 and LDL1 to GDLB0. The multiplexer drivers MUX1 to MUX4 provide BLDE1 to BLDE4 respectively, which couple the other LDLs LDL2 to LDL9 to VPLT through the respective bleed transistors 744.

In some embodiments, multiplexers may be activated on both sides of the sense amplifier in order to match capacitance between the signal and reference GDLs. Using the example above, a row address is received which indicates WL101 in patch 710. Accordingly, the signal will be along GDLB0 and the reference will be GDLT0. The multiplexer drivers MUXDL0 and MUXDR0 provide the signals MUXE0 to both patches 710 and 730. This causes the LDLs LDL0 and LDL1 in both patches 710 and 730 to be coupled to GDLB0 and GDLT0 respectively. The multiplexer driver MUXDL0 and MUXDR0 provide BLDE0 at an inactive level. The other multiplexer drivers MUXDL1 to MUXDL39 and MUXDR1 to MUXDR39 provide MUXE1 to MUXE39 at an inactive level and BLDE1 to BLDE39 at an active level.

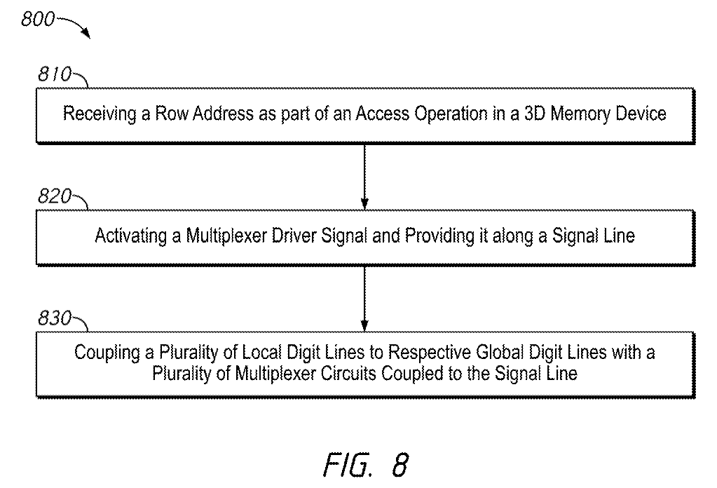

FIG. 8 is a flow chart of a method of selectively coupling local digit lines to global digit lines in a 3D memory device according to some embodiments of the present disclosure. The method 800 may, in some embodiments, be performed by any of the apparatuses and/or systems described herein. For example, the method 800 may be performed by the memory device 100 of FIG. 1, the memory sections 200a of FIG. 2A 200b of FIG. 2B, the memory array 300 of FIG. 3, the memory device 400 of FIG. 4, the cross-section 500 of FIG. 5 600 of FIG. 6, and/or 700 of FIG. 7.

The method 800 generally begins with box 810 which describes receiving a row address as part of an access operation in a 3D memory device. The row address specifies a word line in the 3D memory device.

Box 810 is generally followed by box 820, which describes activating a multiplexer driver signal and providing along a signal line. For example, the method 800 may include decoding the row address with a global row decoder (e.g., 166 of FIG. 1). The method 800 may include selecting a multiplexer driver (e.g., 176 of FIG. 1 314/316 of FIG. 3, 562 of FIG. 5, 642 of FIG. 6, and/or 708 of FIG. 7) based on the decoded row address. The method 800 includes providing a multiplexer enable signal (e.g., MUXE) along the signal line from the selected multiplexer driver.

Box 820 is generally followed by box 830 which describes coupling a plurality of local digit lines to respective global digit lines with a plurality of multiplexer circuits coupled to the signal line. For example, the signal lines may extend in a first direction (e.g., along the x axis), the global digit lines may extend in a second direction (e.g., along a y axis), the local digit lines may extend in a third direction (e.g., along a z axis). The word lines may also extend along the same direction as the signal lines. The method may include activating a word line which intersects the plurality of local digit lines based on the row address.

In some embodiments, the method 800 may include activating a second multiplexer driver based on the row address and providing it along a second signal line in a second patch adjacent to the patch associated with the row address. The method may include coupling a second plurality of local digit lines to respective second global digit lines. The global digit lines and the second global digit lines are coupled to sense amplifiers. The global digit lines may act as signal global digit lines and the second global digit lines may act as reference global digit lines.

In some embodiments, the method 800 may include providing a bleed enable signal from the multiplexer drivers not selected by the row address. The method 800 may include coupling local digit lines not associated with the active word line to a ground voltage responsive to the bleed enable signal.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of word lines extending in a first direction;
a plurality of local digit lines extending in a second direction orthogonal to the first direction;
a plurality of memory cells disposed at the intersection of the plurality of word lines and the plurality of local digit lines;
a plurality of global digit lines extending in a third direction which is orthogonal to both the first direction and the second direction; and
a plurality of first sense amplifiers coupled to a first set of the plurality of global digit lines, wherein at least a portion of the plurality of first sense amplifiers are positioned above at least some of the plurality of memory cells; and
a plurality of second sense amplifiers coupled to a second set of the plurality of global digit lines, wherein the plurality of second sense amplifiers are not above the plurality of memory cells.

2. The apparatus of claim 1, wherein the first set of the plurality of global digit lines are a first half of one of the even or odd ones of the plurality of global digit lines, and
wherein the second set of the plurality of global digit lines are a second half of the one of the even or odd ones of the plurality of global digit lines.

3. The apparatus of claim 2, further comprising:
a plurality of third sense amplifiers coupled to a third set of the plurality of global digit lines, wherein the third set are a first half of a different one of the even or odd ones of the plurality of global digit lines than the one of the even or odd ones of the plurality of global digit lines which comprise the first set and the second set, wherein the plurality of third sense amplifiers are not above the plurality of memory cells; and
a plurality of fourth sense amplifiers coupled to a fourth set of the plurality of global digit lines, wherein the fourth set are a second half of the different one of the even or odd ones of the plurality of global digit lines, wherein at least a portion of the plurality of fourth sense amplifiers are positioned above at least some of the plurality of memory cells.

4. The apparatus of claim 1, further comprising:
a plurality of second word lines extending in the first direction;
a plurality of second local digit lines extending in the second direction;
a plurality of second memory cells disposed at the intersection of the plurality of second word lines and the plurality of second local digit lines; and
a plurality of second global digit lines extending in the third direction,
wherein the plurality of second memory cells are adjacent to the plurality of memory cells along the third direction, and
wherein at least a portion of the plurality of second sense amplifiers are positioned above at least some of the plurality of second memory cells.

5. The apparatus of claim 4, wherein the plurality of first sense amplifiers are coupled to a first set of the plurality of second global digit lines and wherein the plurality of second sense amplifiers are coupled to a second set of the plurality of second global digit lines.

6. The apparatus of claim 4, further comprising an interpatch region positioned between the plurality of memory cells and the plurality of second memory cells, wherein the interpatch region comprises a plurality of conductive elements extending along the second direction, wherein some of the plurality of conductive elements couple the first set of the plurality of global digit lines to the plurality of first sense amplifiers and wherein some of the plurality of conductive elements couple the second set of the plurality of global digit lines to the plurality of second sense amplifiers.

7. The apparatus of claim 6, further comprising a plurality of second conductive elements extending along the third direction, wherein the plurality of second conductive elements couple respective ones of the plurality of conductive elements to respective ones of the plurality of first sense amplifiers or the plurality of second sense amplifiers.

8. The apparatus of claim 1, further comprising a plurality of sub-word line drivers each coupled to a respective one of the plurality of word lines, wherein at least some of the plurality of sub-word line drivers are above at least a portion of the plurality of memory cells.

9. The apparatus of claim 1, further comprising a plurality of multiplexer circuits configured to selectively couple selected ones of the plurality of local digit lines to the plurality of global digit lines.

10. An apparatus comprising:
a first 3D memory patch comprising:
a plurality of word lines extending in a first direction;
a first local digit line extending in a second direction orthogonal to the first direction, wherein the first local digit line is coupled to a first plurality of memory cells at the intersection of the first local digit line with the plurality of word lines;
a second local digit line extending in the second direction, wherein the second local digit line is coupled to a second plurality of memory cells at the intersection of the second local digit line with the plurality of word lines;
a first global digit line coupled to the first local digit line and extending in a third direction orthogonal to the first direction and the second direction; and
a second global digit line coupled to the second local digit line and extending in the third direction, wherein the second global digit line is adjacent to the first global digit line;
a first sense amplifier coupled to the first global digit line, the first sense amplifier positioned above the 3D memory patch; and
a second sense amplifier coupled to the second global digit line, the second sense amplifier positioned above a second 3D memory patch different than the first 3D memory patch.

11. The apparatus of claim 10, wherein the second 3D memory patch is adjacent to the first 3D memory patch along the third direction.

12. The apparatus of claim 10, further comprising:
a first interpatch region positioned between the first 3D memory patch and the second 3D memory patch;
a second interpatch region positioned on an opposite side of the first 3D memory patch from the first interpatch region,
wherein the first sense amplifier is coupled to the first global digit line through the second interpatch region and wherein the second sense amplifier is coupled to the second global digit line through the first interpatch region.

13. The apparatus of claim 12, further comprising:
a first conductive element extending in the second direction in the second interpatch region;
a second conductive element extending in the third direction, wherein the first sense amplifier is coupled to the first global digit line along the first and the second conductive elements;
a third conductive element extending in the second direction in the first interpatch region; and
a fourth conductive element extending in the third direction, wherein the second sense amplifier is coupled to the second global digit line along the third and the fourth conductive elements.

14. The apparatus of claim 10, further comprising:
a first multiplexer circuit configured to selectively couple the first local digit line to the first global digit line responsive to a command signal; and
a second multiplexer circuit configured to selectively couple the second local digit line to the second global digit line responsive to the command signal.

15. An apparatus comprising:
a memory patch comprising a 3D array of memory cells disposed at the intersection of word lines extending in a first direction and local digit lines extending in a second direction, wherein sets of the local digit lines are coupled together by global digit lines extending in a third direction;
a first sense amplifier region positioned above the memory patch in the second direction wherein the first sense amplifier region includes sense amplifiers coupled to a first plurality of the global digit lines; and
a second sense amplifier region positioned above the memory patch in the second direction, wherein the second sense amplifier region includes sense amplifiers coupled to a second plurality of the global digit lines;
a third sense amplifier region which includes sense amplifiers coupled to a third plurality of the global digit lines; and
a fourth sense amplifier region which includes sense amplifiers coupled to a fourth plurality of the global digit lines.

16. The apparatus of claim 15, wherein the third sense amplifier region and the fourth sense amplifier region are not positioned above the memory patch.

17. The apparatus of claim 15, wherein the first plurality of global digit lines are even ones of a first half of the plurality of global digit lines,
wherein the third plurality of global digit lines are even ones of a second half of the plurality of global digit lines,
wherein the second plurality of global digit lines are odd ones of the second half of the plurality of global digit lines, and
wherein the fourth plurality of global digit lines are odd ones of the first half of the plurality of global digit lines.

18. The apparatus of claim 15, further comprising:
a second memory patch comprising a second 3D array of memory cells; and
a third memory patch comprising a third 3D array of memory cells, wherein the memory patch is positioned between the second memory patch and the third memory patch,
wherein the third sense amplifier region is positioned above the second memory patch, and
wherein the fourth sense amplifier region is positioned above the third memory patch.

19. The apparatus of claim 15, further comprising a plurality of multiplexers configured to selectively couple a subset of the local digit lines to the associated global digit line.

20. The apparatus of claim 16, further comprising a plurality of multiplexer drivers, wherein a selected one of the plurality of multiplexer drivers is configured to activate selected ones of the plurality of multiplexer drivers.
